(19) United States
(12) Patent Application Publication
(10) Pub. No.: US 2016/0314981 A1
(43) Pub. Date: Oct. 27, 2016

(54) METHODS FOR FORMING PATTERN USING CYCLIC PROCESSING

(71) Applicant: Samsung Electronics Co., Ltd., Suwon-si (KR)

(72) Inventors: Junho YOON, Suwon-si (KR); KyungYub JEON, Yongin-si (KR); Kyohyeok KIM, Seoul (KR); Jaehong PARK, Seongnam-si (KR); Je-Woo HAN, Hwaseong-si (KR)

(21) Appl. No.: 15/084,479

(22) Filed: Mar. 30, 2016

(30) Foreign Application Priority Data
Apr. 27, 2015 (KR) 10-2015-0059148

(51) Int. Cl. H01L 21/3065; H01L 21/02; H01L 21/308

(52) U.S. Cl. CPC H01L 21/3065; H01L 21/3081; H01L 21/3085; H01L 21/02236

(57) ABSTRACT

A method for forming a vertical pattern includes forming a tungsten layer on a lower layer and performing a cyclic process including an etch process and an oxidation process on the tungsten layer to form a vertical pattern. Performing the cyclic process includes oxidizing the tungsten layer by an oxidation process using oxygen plasma to form a tungsten oxide layer and selectively etching the tungsten oxide layer by an etch process using a chlorine-based gas.

### CROSS-REFERENCE TO RELATED APPLICATIONS

This application claims priority under 35 U.S.C. §119 to Korean Patent Application No. 10-2015-0059148, filed Apr. 27, 2015, in the Korean Intellectual Property Office, the entirety of which is hereby incorporated by reference.

### BACKGROUND

Embodiments of the present disclosure relate to semiconductors and, more particularly, to methods for forming a pattern using a cyclic process.

In a process of manufacturing a semiconductor device, an etch process is generally used to form a vertical pattern. Conventionally, a sidewall of the vertical pattern may be undesirably etched during the etching process for the formation of the vertical pattern, so an undercut may be formed in the vertical pattern. Accordingly, there is a need for a process to form a vertical pattern without formation of an undercut.

### SUMMARY

Example embodiments may provide methods for forming a pattern without formation of an undercut.

Example embodiments may also provide methods for forming a pattern with improved distribution.

In one aspect, a method for forming a pattern may include forming a tungsten layer on a lower layer, and performing a cyclic process comprising an etch process and an oxidation process on the tungsten layer to form a vertical pattern. Performing the cyclic process may include oxidizing the tungsten layer by the oxidation process using oxygen plasma to form a tungsten oxide layer and selectively etching the tungsten oxide layer by the etch process using a chlorine-based gas. Each of the oxidation process and the etch process may use plasma generated by a first power applied to a top electrode and a second power applied to a bottom electrode. The plasma used in the oxidation process may be generated under a condition where the first power is greater than the second power, and the plasma used in the etch process may be generated under a condition where the second power is greater than the first power.

In example embodiments, the method may further include selectively etching the tungsten layer to form a first hole having a first depth in the tungsten layer. Performing the cyclic process may further include forming a first tungsten oxide layer covering an inner surface of the first hole by means of the oxidation process, and selectively removing the first tungsten oxide layer disposed on a floor surface of the first hole by means of the etch process to expose a portion of the tungsten layer through the floor surface of the first hole.

In example embodiments, the performing the cyclic process may further include further removing the exposed portion of the tungsten layer by the etch process to form a second hole having a second depth greater than the first depth and forming a second tungsten oxide layer covering an inner surface of the second hole by means of the oxidation process.

In example embodiments, the selectively removing the first tungsten oxide layer may include allowing a portion of the first tungsten oxide layer to remain on an inner sidewall of the first hole.

In example embodiments, the method may further include forming a mask layer on the tungsten layer. The selectively removing the tungsten layer to form a first hole may include etching the tungsten layer to form the first hole by means of an etch process using the mask layer as an etch mask.

In example embodiments, the etching the tungsten layer to form the first hole may further include forming a polymer layer on the mask layer. The polymer layer may include an etching by-product generated during the formation of the first hole. The polymer layer may be removed by the oxidation process.

In example embodiments, the oxygen plasma may further include hydrogen or a hydrocarbon-based gas including hydrogen.

In example embodiments, the etch process may use a mixed gas in which at least one of boron, a boron-containing gas or an inert gas is mixed with the chlorine-based gas.

In example embodiments, the method may further include patterning the lower layer by means of an etch process using the vertical pattern as an etch mask.

In example embodiments, the lower layer may include at least one of a silicon layer, a silicon oxide layer, or a silicon oxynitride layer.

In another aspect, a method for forming a pattern may include forming a tungsten-containing layer on a lower layer, forming a mask layer on the tungsten-containing layer, patterning the tungsten-containing layer by means of an etch process using the mask layer as an etch mask to form a hole in the tungsten-containing layer, oxidizing the tungsten-containing layer by means of an oxidation process using oxygen plasma such that a tungsten oxide layer is formed to cover an inner surface of the hole, etching the tungsten oxide layer by means of an etch process using a chlorine-based gas to selectively remove the tungsten oxide layer on a floor surface of the inner surface of the hole and to allow the tungsten oxide layer to remain on an inner sidewall of the inner surface of the hole, and removing the tungsten-containing layer exposed through the floor surface of the hole by means of the etch process using the chlorine-based gas. The oxidation process using the oxygen plasma and the etch process using the chlorine-based gas may be performed in a chamber to which opposite top and bottom electrodes are provided. The oxidation process may use plasma generated under a condition where a first power applied to the top electrode is greater than a second power applied to the bottom electrode, and the etch process may use plasma generated under a condition where the second power applied to the bottom electrode is greater than the first power applied to the top electrode.

In example embodiments, the method may further include, after removing the tungsten-containing layer exposed through the floor surface of the hole by means of the etch process using the chlorine-based gas, performing the oxidation process using the oxygen plasma and the etch process using the chlorine-based gas one or more times to increase a depth of the hole, thereby exposing the lower layer.

In example embodiments, the tungsten-containing layer may include a tungsten (W) layer or a tungsten nitride (WN) layer, and the tungsten oxide layer may include a WO layer.

In example embodiments, the chlorine-based gas may contain Cl₂, CCl₄, BCl₃ or a combination thereof.

In example embodiments, the etch process using the chlorine-based gas may use a mixed gas in which boron (B) or BCl₃ is mixed with the Cl₂, CCl₄, BCl₃ or the combination thereof.

In example embodiments, the oxygen plasma may include oxygen (O₂) and a gas adjusting an oxidation rate of the tungsten-containing layer. The gas adjusting an oxidation rate of the tungsten-containing gas may include H₂, CH₄, CHF₃, CH₃F, C₂H₆, C₂H₄, or a combination thereof.

In still another aspect, a method for forming a pattern may include loading a substrate having a metal layer thereon on a bottom electrode in a chamber, the chamber including a top electrode and the bottom electrode, performing a cyclic process to pattern the metal layer, and repeatedly performing the cyclic process to form a vertical pattern on the substrate. The performing the cyclic process may include oxidizing the metal layer by means of an oxidation process using oxygen plasma generated under a condition where a first power applied to the top electrode is greater than a second power applied to the bottom electrode, thereby forming a passivation covering a surface of the metal layer, and selectively removing the passivation layer by means of an etch process using chlorine-based gas plasma generated under a condition where the second power applied to the bottom electrode is greater than the first power applied to the top electrode, thereby exposing a portion of the surface of the metal layer. The repeatedly performing the cyclic process may include successively removing the exposed portion of the surface of the metal layer to form the vertical pattern.

In example embodiments, the metal layer may include tungsten, and the passivation layer may include a tungsten oxide layer. A ratio of a process time of the oxidation process to a process time of the etch process may be one to one (1:1).

In example embodiments, performing the cyclic process to pattern the metal layer may include forming a hole partially penetrating the metal layer to extend toward the substrate. The cyclic process may be repeatedly performed to increase a depth of the hole.

In example embodiments, the passivation layer may cover an inner sidewall of the hole, and a portion of the passivation layer covering a floor surface of the hole may be removed by means of the etch process.

### BRIEF DESCRIPTION OF THE DRAWINGS

The forgoing and other features of disclosed embodiments will be described below in more detail with reference to the accompanying drawings of non-limiting embodiments of disclosed embodiments in which like reference characters refer to like parts throughout the different views. The drawings are not necessarily to scale, emphasis instead being placed upon illustrating principles of the disclosed concepts. In the drawings:

FIGS. 1A to 1I are cross-sectional views illustrating a method for forming a vertical pattern according to an example embodiment;

FIG. 2A is a graph showing variation in width of a hole in a method for forming a vertical pattern according to an example embodiment;

FIG. 2B is a graph showing the distribution of a hole in a method for forming a vertical pattern according to an example embodiment;

FIGS. 3A to 3C are cross-sectional views illustrating a method for forming a gate using a method for forming a vertical pattern according to an example embodiment;

FIGS. 4A to 4C are cross-sectional views illustrating a method for forming a bottom electrode of a capacitor using a method for forming a vertical pattern according to an embodiment;

FIGS. 5A to 5C are cross-sectional views illustrating a method for patterning a semiconductor substrate using a method for forming a vertical pattern according to an example embodiment;

FIG. 6A is a cross-sectional view of a semiconductor manufacturing apparatus using capacitively-coupled plasma according to an example embodiment;

FIG. 6B is a cross-sectional view of a semiconductor manufacturing apparatus using inductively-coupled plasma according to an example embodiment;

FIG. 7A is a schematic block diagram illustrating a memory card including a semiconductor device according to example embodiments; and

FIG. 7B is a schematic block diagram illustrating an information processing system including a semiconductor device according to example embodiments.

### DETAILED DESCRIPTION

Methods for forming vertical patterns according to example embodiments will now be described more fully with reference to accompanying drawings.

Example embodiments will now be described more fully with reference to the accompanying drawings, in which some example embodiments are shown. Example embodiments may, however, be embodied in many different forms and should not be construed as being limited to the embodiments set forth herein; rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements, and thus their description may be omitted.

Advantages and features of the present disclosure may be understood more readily by reference to the following detailed description of example embodiments and the accompanying drawings. The present disclosure may, however, be embodied in many different forms and should not be construed as being limited to the embodiments set forth herein. In the drawings, the thickness of layers and regions are exaggerated for clarity.

It will be understood that when an element or layer is referred to as being “on,” “connected to,” or “in contact with” another element or layer, it can be directly on, connected to, or in contact with the other element or layer or intervening elements or layers may be present. In contrast, when an element is referred to as being “directly on,” “directly connected to,” or “in direct contact with” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. Unless the context indicates otherwise, these terms are only used to distinguish one element from another element. Thus, for example, a first element, a first component or a first section discussed below could be termed a second element, a second component or a second section without departing from the teachings of the present disclosure. In addition, in certain cases, even if a term is not described using “first,” “second,” etc. in the specification, it may still be referred to as “first” or “second” in a claim in order to distinguish difference claimed elements from each other.

As used herein, a semiconductor device may refer to various devices, and may also refer, for example, to one or more transistors, logic devices, or cell arrays, or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, a hard drive including additional components, or a mobile phone, laptop, tablet, desktop, camera or other consumer electronic device, etc.

The present disclosure will be described with reference to perspective views, cross-sectional views, and/or plan views, in which example embodiments are shown. Thus, the profile of an exemplary view may be modified according to manufacturing techniques and/or allowances. That is, the embodiments of the invention are not intended to limit the scope of the present disclosure but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which this disclosure belongs. It is noted that the use of any and all examples, or exemplary terms provided herein is intended merely to better illuminate the embodiments and is not a limitation on the scope unless otherwise specified. Further, unless defined otherwise, all terms defined in generally used dictionaries may not be overly interpreted.

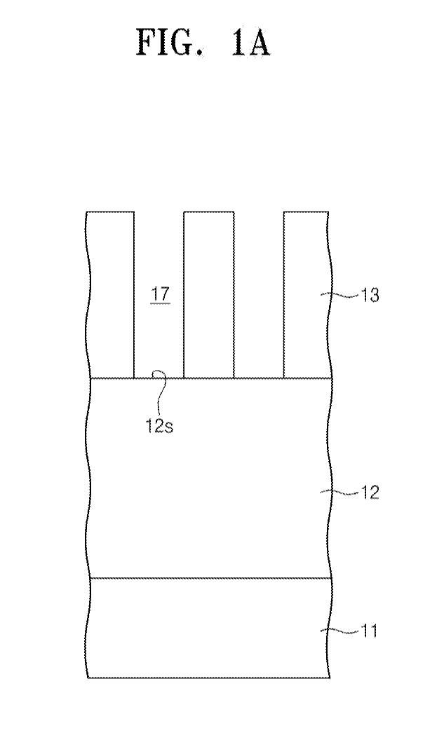

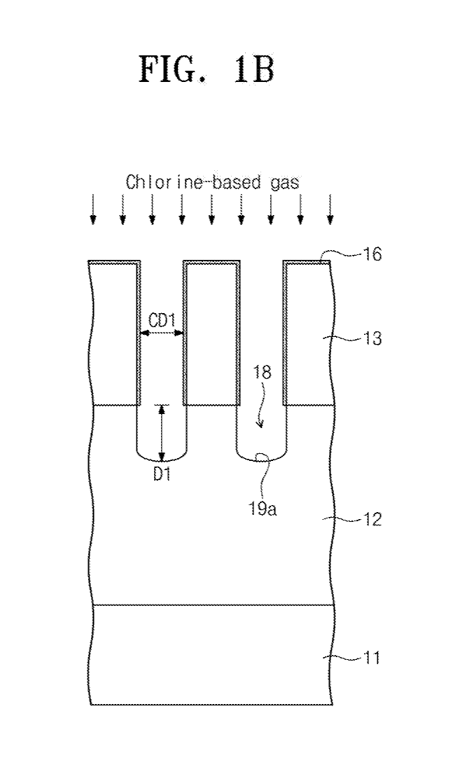

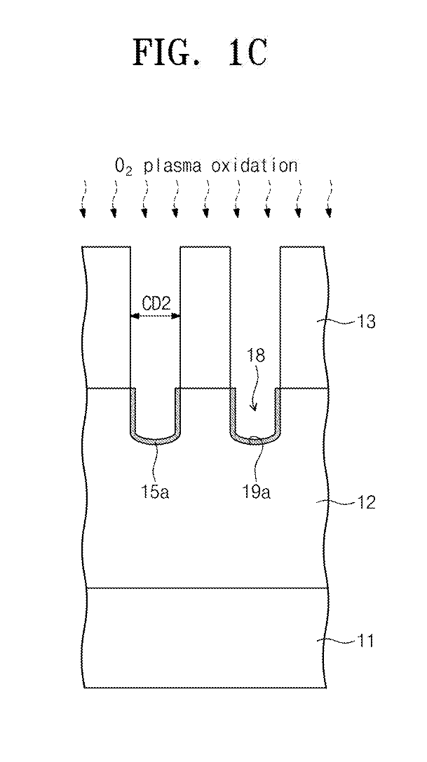

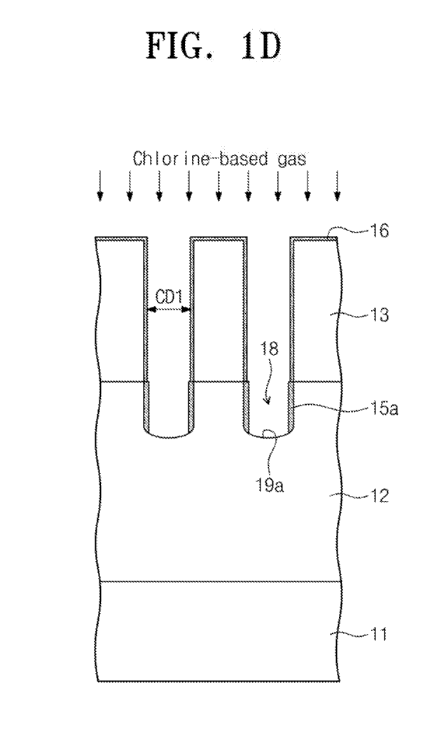

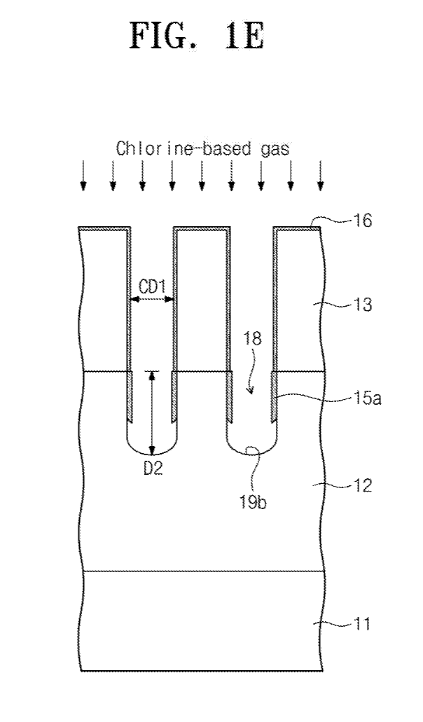

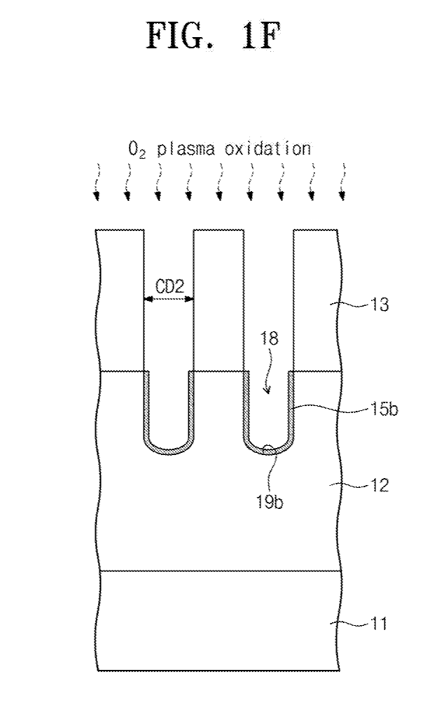

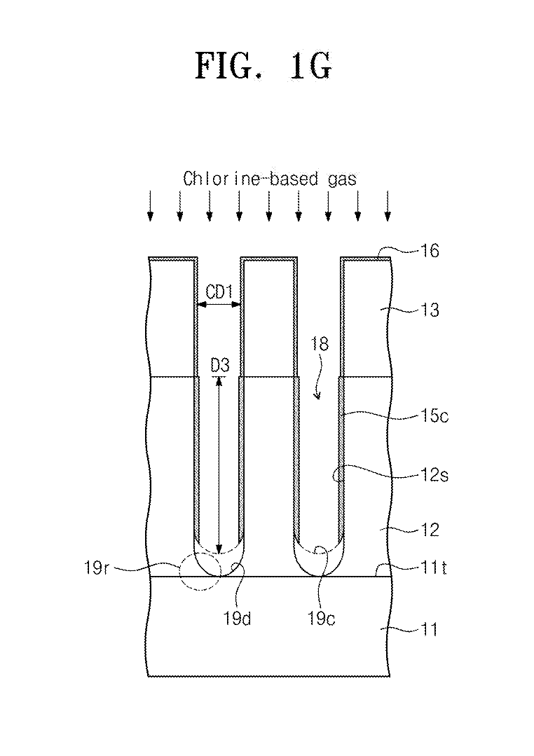

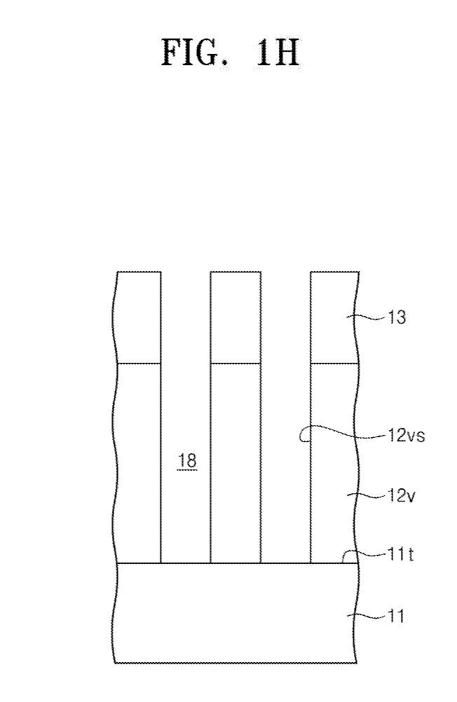

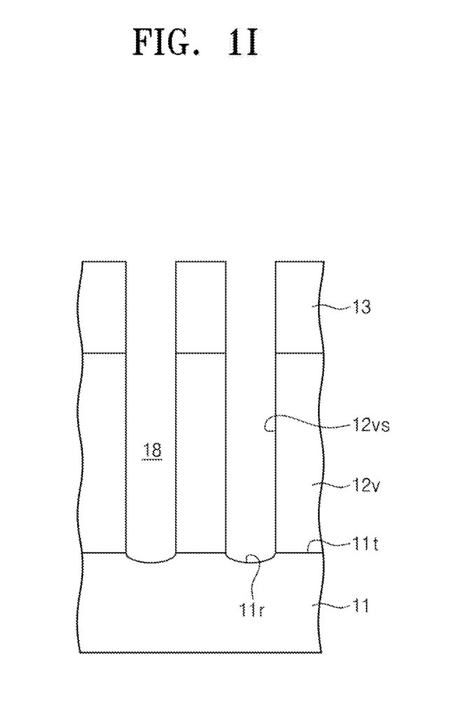

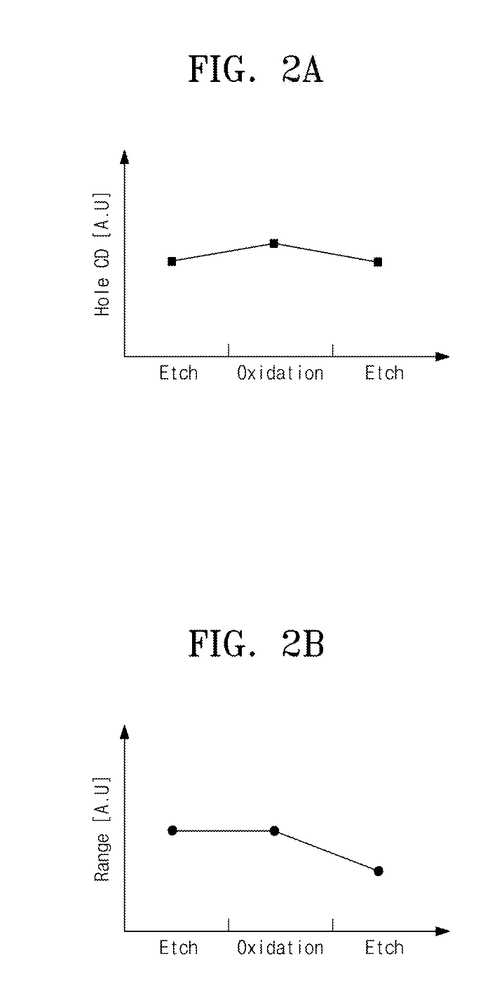

FIGS. 1A to 1I are cross-sectional views illustrating a method for forming a vertical pattern according to an example embodiment of the disclosed concepts. FIG. 2A is a graph showing variation in width of a hole in a method for forming a vertical pattern according to an example embodiment of the disclosed concepts, and FIG. 2B is a graph showing the distribution of a hole in a method for forming a vertical pattern according to an example embodiment of the disclosed concepts.

Referring to FIG. 1A, a metal layer 12 may be formed on a lower layer 11. The metal layer 12 may include tungsten (W), aluminum (Al), cobalt (Co), nickel (Ni), titanium (Ti), tantalum (Ta), or an alloy or nitride thereof. In example embodiments, the metal layer 12 may be a tungsten (W) layer or a tungsten nitride (WN) layer. The lower layer 11 may include a material having an etch selectivity with respect to the metal layer 12. For example, the lower layer 11 may include a silicon layer, a silicon oxide layer, a silicon nitride layer, or a combination thereof. In example embodiments, the lower layer 11 may be a silicon (Si) layer.

A mask layer 13 may be formed on the metal layer 12. The mask layer 13 may include a silicon oxide layer, a silicon nitride layer, or a combination thereof. Alternatively, the mask layer 13 may be a photoresist layer. The mask layer 13 may have an opening 17 that is in the form of a hole or a line when viewed in plan view. In example embodiments, the opening 17 may be in the form of a hole.

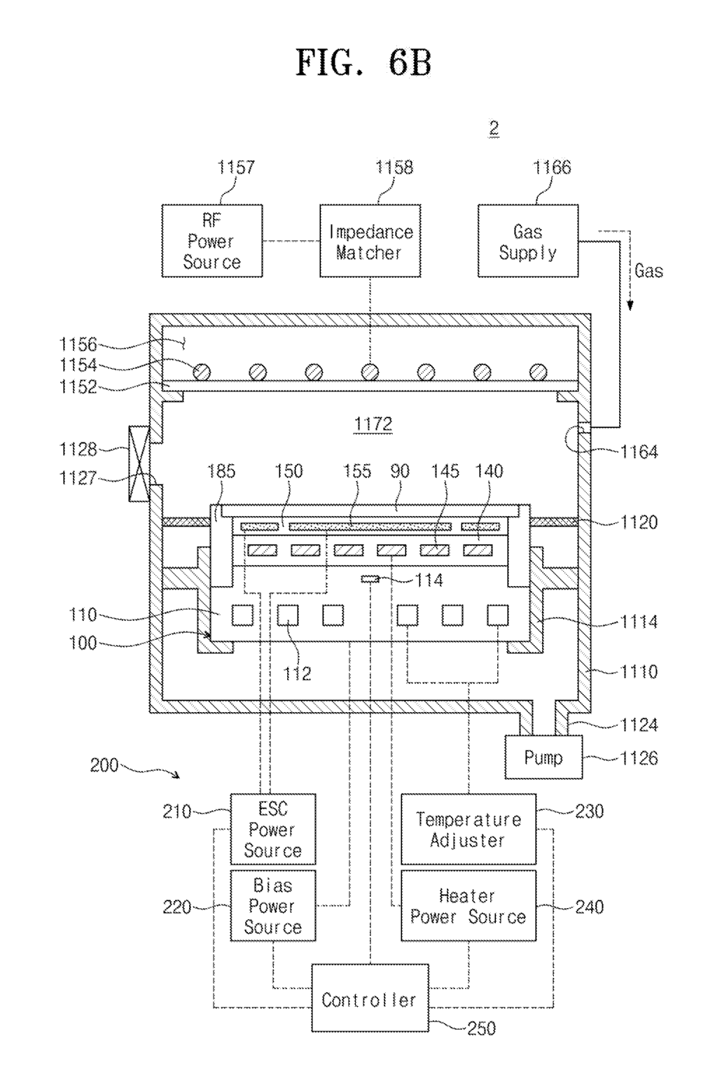

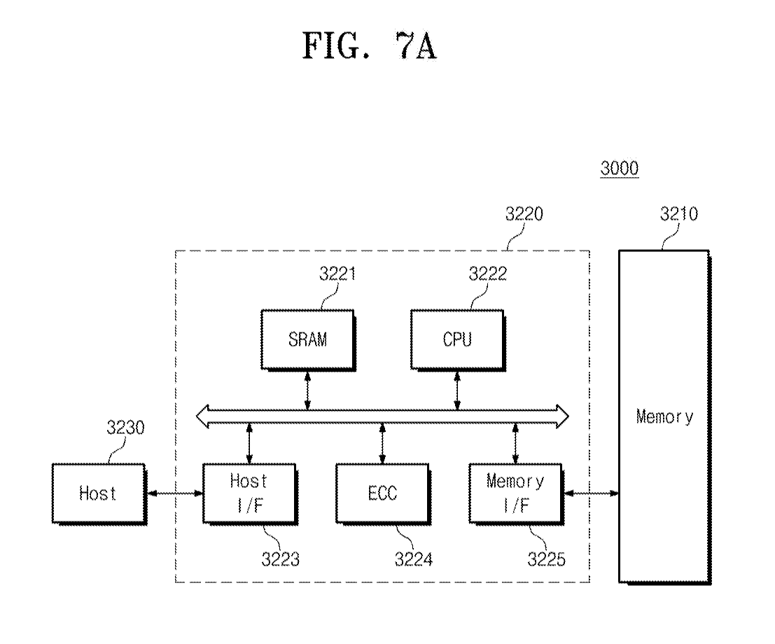

By-products that occur during a process for forming the mask layer 13 may be removed. For example, a plasma process may be performed to remove a metal oxide (e.g., tungsten oxide) or carbon compound covering a surface 12s of the metal layer 12 exposed through the opening 17. The process of removing the by-products (hereinafter, referred to as “a breakthrough process”) may be performed in a semiconductor manufacturing apparatus 1 using capacitively-coupled plasma (CCP), as disclosed and described in connection with FIG. 6A, or a semiconductor manufacturing apparatus 2 using inductively-coupled plasma (ICP), as disclosed and described in connection with FIG. 6B. A description of the breakthrough process will be made later with reference to FIG. 6A or 6B.

Referring to FIG. 1B, the metal layer 12 may be etched by an etch process (e.g., a plasma etch process) using the mask layer 13 as an etch mask. An etch gas may contain fluorine (F) and/or chlorine (Cl). In example embodiments, the etch process may be performed using a fluorine-based etch gas (e.g., CF₄, CHF₃, and/or SF₆), a chlorine-based etch gas (e.g., Cl₂, CCl₄, and/or BCl₃), or a mixed etch gas of the fluorine-based etch gas and the chlorine-based etch gas.

According to example embodiments, such as the embodiment illustrated in FIG. 1B, the metal layer 12 may be etched using the chlorine-based etch gas such as Cl₂, CCl₄, and/or BCl₃. The etch gas may further include an inert gas such as argon (Ar) and helium (He) to generate plasma.

A hole 18 having a first depth D1 may be formed in the metal layer 12 by the etching process. The hole 18 may have a first floor surface 19a. The first floor surface 19a may be uneven, e.g., concave or convex toward the lower layer 11 or may be even. The mask layer 13 may be covered with an etching by-product. When the etch process uses the chlorine-based etch gas and the metal layer 12 includes tungsten, a polymer layer 16 such as WCl₄ may be formed on the mask layer 13. The polymer layer 16 may be formed on an inner sidewall of the hole 18.

The hole 18 may seem to have a first critical dimension CD1. When the hole 18 is viewed in plan view (i.e., viewed from the top of the mask layer 13 in a direction toward the metal layer 12), the first critical dimension CD1 may mean an apparent width of the hole 18. Hereinafter, the term critical dimension CD will be identically applied.

Referring to FIG. 1C, a first passivation layer 15a may be formed to cover an inner surface of the hole 18. For example, an oxygen (O₂) plasma process may be performed to form the first passivation layer 15a covering the inner surface of the hole 18. When the metal layer 12 is a tungsten layer, the first passivation layer 15a may include WₓO_{y}. It is known that a bonding energy of W—W is about 3.4 eV, a bonding energy of W—O is about 6.53 eV, a bonding energy of OW—O is about 6.32 eV, and a bonding energy of O₂W—O is about 5.98 eV. The first passivation layer 15a may be a WO layer having a relatively high bonding energy. The polymer layer 16 may be removed by the oxygen plasma process. Due to the removal of the polymer layer 16, the hole 18 may seem to have a second critical dimension CD2 that is greater than the first critical dimension CD1.

Referring to FIG. 1D, the metal layer 12 may be etched by an etch process. The etch process may be performed using the above-mentioned chlorine-based etch gas such as Cl₂, CCl₄, BCl₃ or a combination thereof. A portion of the first passivation layer 15a (e.g., a portion of the first passivation layer 15a formed on the first floor surface 19a of the hole 18) may be removed by the etch process. Thus, the first floor surface 19a of the hole 18, i.e., a portion of the metal layer 12 may be exposed. The first passivation layer 15a formed on the inner sidewall of the hole 18 may not be etched owing to a mask shadow. A polymer (e.g., WCl₄), which is a by-product of the etch process, may be accumulated on the mask layer 13 to form the polymer layer 16. The polymer layer 16 may be further formed on the first passivation layer 15a. Due to the formation of the polymer layer 16, the hole 18 may seem to have the first critical dimension CD1 smaller than the second critical dimension CD2.

Referring to FIG. 1E, when the etch process is continuously performed, the hole 18 may have a second depth D2 greater than the first depth D1. In other words, the hole 18 may have a second floor surface 19b deeper than the first floor surface 19a. The second floor surface 19b may be uneven, e.g., convex or concave toward the lower layer 11 or may be even. The first passivation layer 15a formed on the inner sidewall of the hole 18 may remain because it may not be etched owing to the mask shadow. Accordingly, the inner sidewall of the hole 18 may not be etched, i.e., an undercut may not be formed by the passivation layer 15a even when the etch process is performed.

Referring to FIG. 1F, a second passivation layer 15b may be formed by an oxygen (O₂) plasma process. The second passivation layer 15b may be formed on an inner surface of the hole 18. Thus, the second floor surface 19b of the hole 18 may be covered with the second passivation layer 15b. The polymer layer 16 may be removed by the oxygen plasma process. Accordingly, the hole 18 may seem to have the second critical dimension CD2 greater than the first critical dimension CD1.

A composition of the second passivation layer 15b may be the same as or similar to that of the first passivation layer 15a. For example, when the first passivation layer 15a is a WO layer, a reaction expressed by the following formula 1 may be predominant over a reaction expressed by the following formula 2 although oxygen penetrates into the first passivation layer 15a. For this reason, the second passivation layer 15b may be a WO layer. Since the reaction expressed by the following formula 1 is predominant over the reaction expressed by the following formula 2, a thickness of the second passivation layer 15b may be equal or similar to that of the first passivation layer 15a. That is, although the remaining first passivation layer 15a is oxidized to form the second passivation layer 15b, there may be a limitation in increasing the thickness of the second passivation layer 15b.

WO+O→WO₂ [FORMULA 1]

W+O→WO [FORMULA 2]

Referring to FIG. 1G, an oxidation process and an etch process may be repeatedly performed. For example, the hole 18 may be further etched by the etch process to have a third depth D3 greater than the second depth D2. Thus, the hole 18 may have a third floor surface 19c deeper than the second floor surface 19b. The third floor surface 19c may be uneven, e.g., concave or convex toward the lower layer 11 or may be even. A third passivation layer 15c may be formed by an oxidation process to cover an inner surface of the hole 18. A portion of the third passivation layer 15c covering the third floor surface 19c of the hole 18 may be removed by means of an etch process, and then the metal layer 12 exposed through the third floor surface 19c may be etched by continuously performing the etch process such that a fourth floor surface 19d may emerge to expose a portion of the lower layer 11.

According to example embodiments, the metal layer 12 may be vertically patterned by means of a cyclic process in which the oxidation process and the etch process are repeatedly performed, as described with reference to FIGS. 1B to 1G. When an oxidation rate is higher than an etch rate in the cyclic process, a failure of the etch process may occur. Meanwhile, when the etch rate is higher than the oxidation rate, an undercut may be formed. According to example embodiments, oxygen may be further supplied during the oxygen plasma process so as to adjust the oxidation rate, and boron may be further supplied to the chlorine-based etch gas so as to adjust the etch rate.

As an example of adjusting the oxidation rate, when the first passivation layer 15a is formed, as described in connection with FIG. 1C, hydrogen (H₂) or a hydrocarbon-based gas including hydrogen (e.g., CH₄, CHF₃, CH₃F, C₂H₆, C₂H₄, or a combination thereof) may be mixed with oxygen to initiate a reduction reaction during the oxidation reaction of the metal layer 12. In other words, a first passivation layer 15a formed by a plasma process using a mixed gas of oxygen and hydrogen or a gas mixed with a gas containing oxygen and hydrogen may have a smaller thickness than the first passivation layer 15a formed by the oxygen plasma process. The adjustment of the oxidation rate may be applied to the oxidation processes described with reference to FIGS. 1E and 1G.

As an example of adjusting the etch rate, boron (B) or a boron-containing gas (e.g., BCl₃) may be added to the chlorine-based etch gas (e.g., Cl₂, CCl₄, BCl₃, or a combination thereof) to increase the etch rate. For example, when a portion of the first passivation layer 15a explained in FIG. 1C is etched, boron (B) or the boron-containing gas (e.g., BCl₃) may be added to the chlorine-based etch gas to combine oxygen of WO with the boron. Thus, an etch rate of the first passivation layer 15a may increase. Moreover, argon (Ar) or helium (He) may be added to the chlorine-based etch gas so as to increase the etch rate of the first passivation layer 15a. The adjustment of the etch rate may be applied to the etch processes described with reference to FIGS. 1D, 1E, and 1G.

The oxidation process and the etch process may be performed in a semiconductor manufacturing apparatus 1 using capacitively-coupled plasma (CCP), such as disclosed in connection with FIG. 6A, or a semiconductor manufacturing apparatus 2 using inductively-coupled plasma (ICP), such as disclosed in connection with reference to FIG. 6B. Descriptions of the oxidation process and the etch process will be made later with reference to FIGS. 6A and 6B.

The hole 18 formed by the cyclic process may have a varying critical dimension CD. For example, the hole 18 may seem to have the first critical dimension CD1 due to the polymer layer 16 formed by the etch process. The polymer layer 16 may be removed by the oxidation process such that the hole 18 may seem to have the second critical dimension CD2 greater than the first critical dimension CD1. As shown in FIG. 2A, when the etch process, the oxidation process, and the etch process are performed in order, the hole 18 may seem to have a critical dimension CD whose size is repeated in the order as follows: a small size→a large size→a small size.

A height (or thickness) of the mask layer 13 may be gradually reduced by the etch process repeated according to the cyclic process. For example, the height (or thickness) of the mask layer 13 may be reduced by the etch process for forming the hole 18 as shown in FIG. 1B. The reduction in height (or thickness) of the mask layer 13 may also occur during in the etch processes in FIGS. 1D, 1E, and 1G.

Referring back to FIG. 1G, when the lower layer 11 is a silicon layer and the metal layer 12 is a tungsten layer, a ratio of an etch rate of tungsten to an etch rate of silicon may be high. For example, the ratio of the etch rate of tungsten (W) to the etch rate of silicon (Si) may be equal to or greater than about 10. Thus, although over-etching occurs, the lower layer 11 emerging through the fourth floor surface 19d may be scarcely etched.

The fourth floor surface 19d may be concave or convex toward the lower layer 11 or may be even. When the fourth floor surface 19d is uneven, only a portion of a top surface 11t of the lower layer 11 may restrictively emerge through the hole 18. This may mean that a sidewall 12s of the metal layer 12 is not entirely vertical.

According to example embodiments, to achieve vertical patterning of the metal layer 12, over-etching may be performed to form a fourth flat floor surface 19d. Referring to FIG. 1G, a portion 19r of the metal layer 12 exposed through the hole 18 may be removed by the over-etching. When the portion 19r of the metal layer 12 is removed by the over-etching, the lower layer 11 may not be etched or may be slightly etched. A description of the over-etching will be made in connection with FIGS. 6A and 6B.

The term “over-etching” may mean that the etch process of a cyclic process is performed to over-etch the fourth floor surface 19d of the hole 108 and may not mean that an additional over-etch process is performed. When the top surface 11t of the lower layer 11 emerges through the fourth floor surface 19d by means of the etch process or the sidewall 12s of the metal layer 12 is vertical, the over-etching may not be needed. Meanwhile, when only a portion of the top surface 11t of the lower layer 11 emerges restrictively, the portion 19r of the metal layer 12 may be removed by performing the over-etching. After the etch process or the over-etching, the polymer layer 16 and the third passivation layer 15c may be removed or it may be allowed to remain.

Referring to FIG. 1H, a metal pattern 12v having a vertical sidewall 12vs may be formed by means of the over-etching. The top surface 11t of the lower layer 11 may not be recessed by a high etch selectivity with respect to the metal layer 12. Alternatively, the lower layer 11 may have a recessed top surface 11 under the hole 18 by means of the over-etching, as shown in connection with FIG. 1I.

In FIG. 1G, there may be a case where the fourth floor surface 19d of at least one of a plurality of holes 18 may not reach the top surface 11t of the lower layer 11 due to differences in depths of the plurality of holes 18. In addition, there may be case where critical dimensions CD of the holes 18 are different from each other because volumes of the portions 19r of the metal layer 11 are different from each other. According to example embodiments, since the portion 19r of the metal layer 11 is etched to be removed by means of the over-etching, depth distribution and/or critical dimension distribution of the hole 18 may be improved. As shown in FIG. 2B, when the etch process, the oxidation process, and the etch process are performed in order, depth and/or critical dimension CD distribution of holes 18 having small values may be improved. As described above, the vertical metal pattern 12v shown in FIG. 1H or FIG. 1I may be formed on the lower layer 11 by means of the cyclic process in which the etch process, the oxidation process and the etch process are repeatedly performed. The metal pattern 12v may be used as, for example, a gate or a mask pattern, as will be described later.

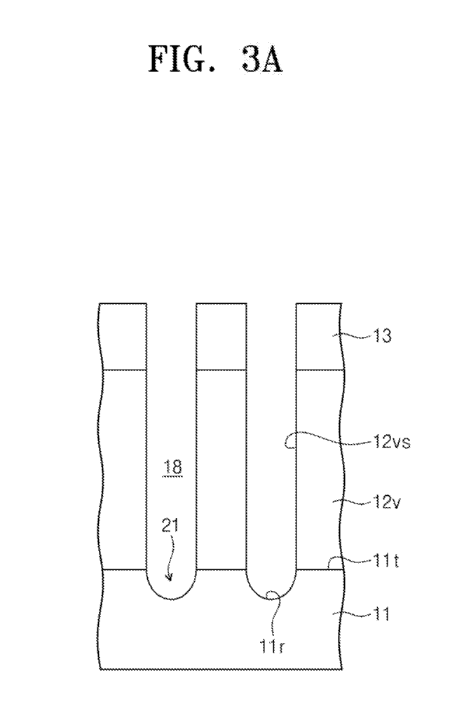

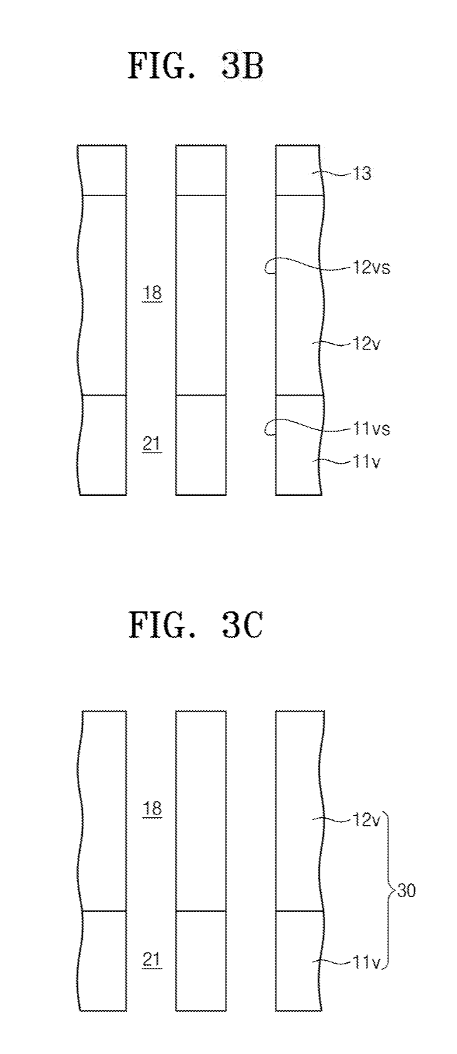

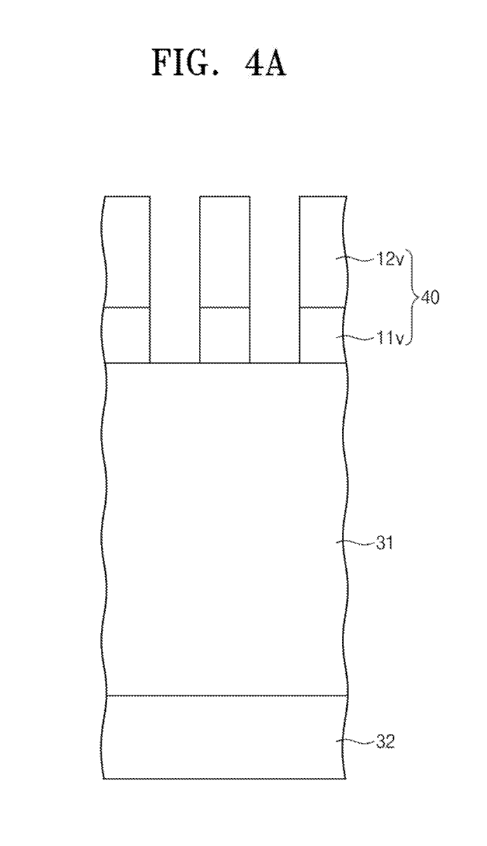

FIGS. 3A to 3C are cross-sectional views illustrating a method for forming a gate using a method for forming a vertical pattern according to an example embodiment.

Referring to FIG. 3A, the lower layer 11 may be etched by an etch process using the vertical metal pattern 12v formed by the cyclic process as a mask. The recessed top surface 11r of the lower layer 11 may be further recessed by the process of etching the lower layer 11 to form a second hole 21 vertically aligned with the hole 18. Before the etch process, a breakthrough process may be further performed to remove by-products that may be produced by the cyclic process. For example, by-products on the surface 11r of the lower layer 11 exposed through the hole 18 may be removed by, for example, a plasma process. Descriptions of the breakthrough process and the etch process will be made in connection with FIGS. 6A and 6B.

Referring to FIG. 3B, the etch process may be continuously performed to form a lower pattern 11v having a vertical sidewall 11vs. The vertical metal pattern 12v and the vertical lower pattern 11v may be vertically aligned with each other. The mask layer 13 may be removed by an etch or ashing process.

Referring to FIG. 3C, the vertical lower pattern 11v and the vertical metal pattern 12v may constitute, for example, a gate 30 having a double-layered structure. For example, the vertical lower pattern 11v may correspond to a lower gate including, e.g., a silicon layer, and the vertical metal pattern 12v may correspond to an upper gate including, e.g., a tungsten layer. The gate 30 may include the lower gate and the upper gate. Since the gate 30 includes the vertical metal pattern 12v including a tungsten layer, a resistance of the gate 30 may be lower than, for example, that of a gate formed of a silicon layer.

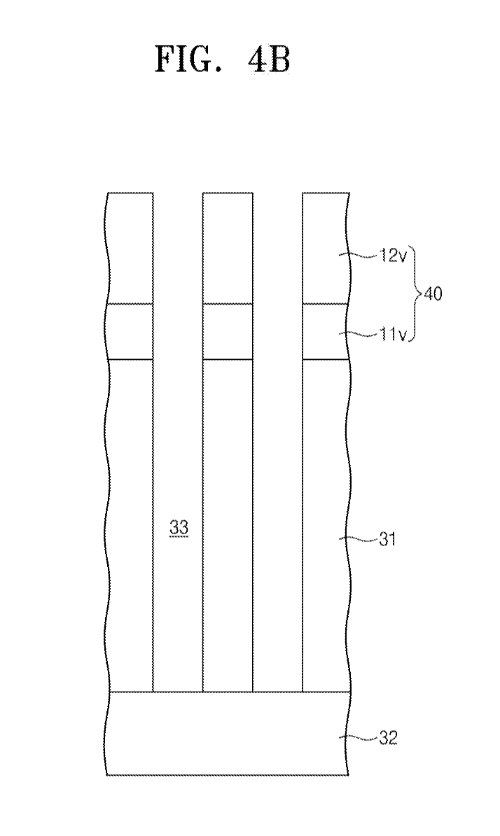

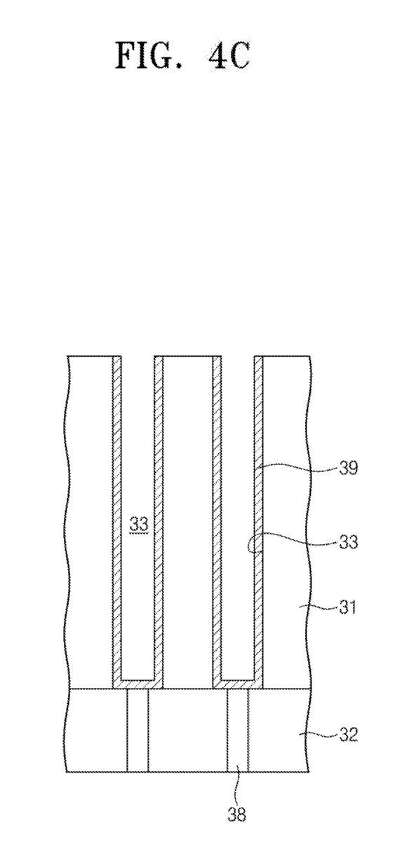

FIGS. 4A to 4C are cross-sectional views illustrating a method for forming a bottom electrode of a capacitor using a method for forming a vertical pattern according to an example embodiment.

Referring to FIG. 4A, the vertical lower pattern 11v and the vertical metal pattern 12v may be used as, for example, a mask layer 40 for patterning an insulating mold layer 31. For example, the mask layer 40 may be formed on the insulating mold layer 31 by the cyclic process according to example embodiments. The insulating mold layer 31 may be formed on a base layer 32 by depositing a silicon oxide layer, a silicon nitride layer or a combination thereof. The base layer 32 may be any layer such as an insulating layer, a conductive layer, or a semiconductor substrate.

Referring to FIG. 4B, a vertical hole 33 may be formed to penetrate the insulating layer 31 by means of an etch process using the mask layer 40 as an etch mask. The mask layer 40 may be removed after formation of the vertical hole 33.

Referring to FIG. 4C, a cylindrical or cup-shaped capacitor bottom electrode 39 may be formed in the vertical hole 33. The base layer 32 may be an insulating layer, and a contact plug 38 may be formed in base layer 32 so as to be electrically connected to the capacitor bottom electrode 39. According to example embodiments, distribution of width and/or depth of the vertical hole 33 may be improved to form the capacitor bottom electrode 39 having a uniform area.

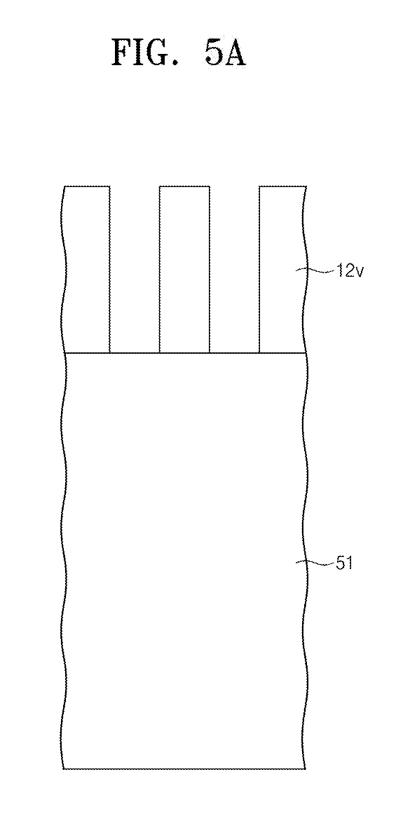

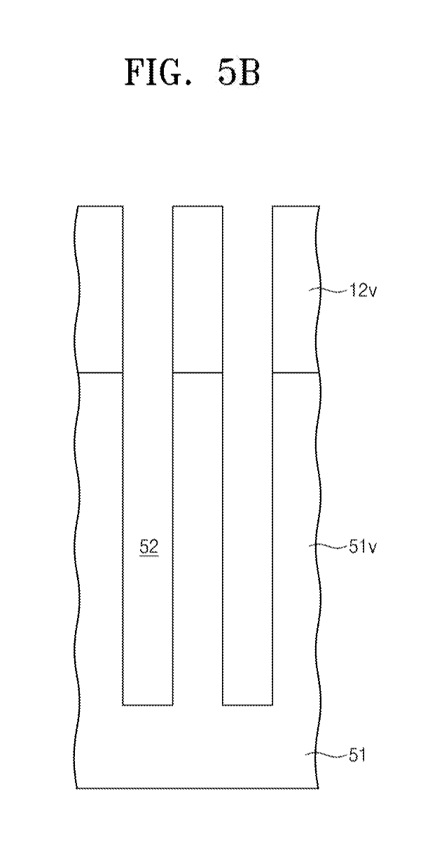

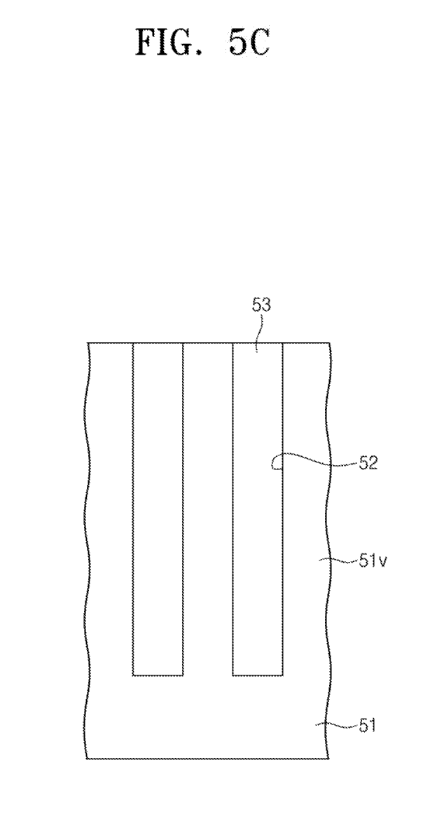

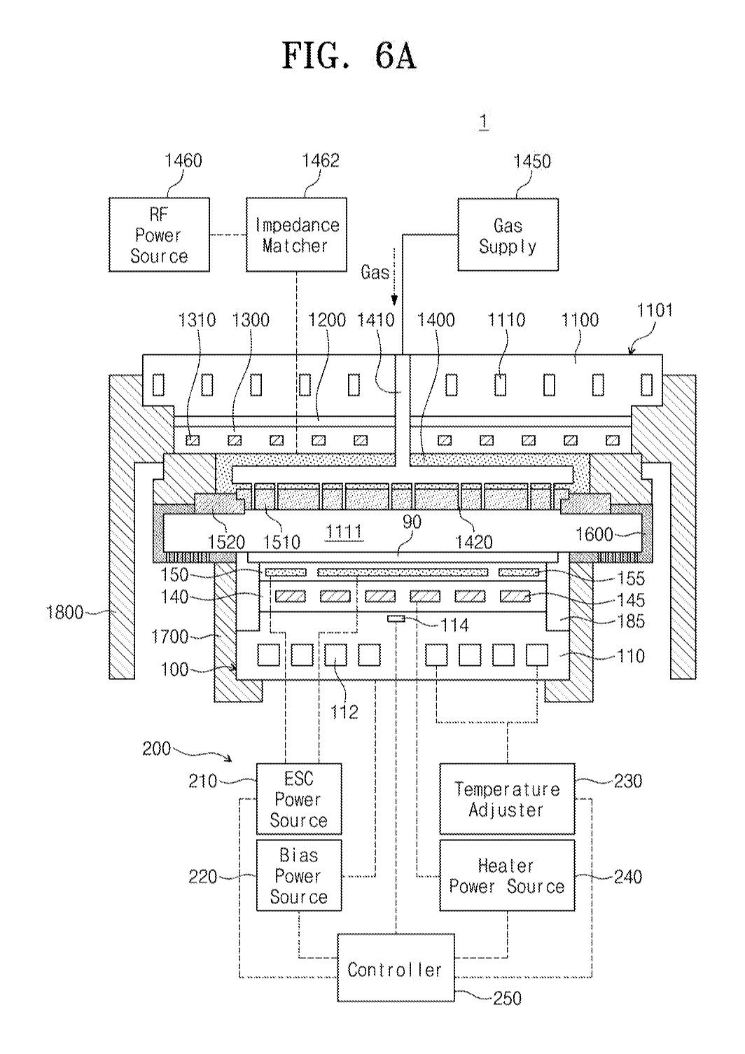

FIGS. 5A to 5C are cross-sectional views illustrating a method for patterning a semiconductor substrate using a method for forming a vertical pattern according to an example embodiment.

Referring to FIG. 5A, the vertical metal pattern 12v may be used as a mask pattern. For example, the vertical metal pattern 12v may be formed on a semiconductor substrate 51 by means of the cyclic process according to example embodiments.

Referring to FIG. 5B, the semiconductor substrate 51 may be patterned by means of an etch process using the vertical metal pattern 12v as an etch mask such that a trench 52 may be formed to divide a vertical upright active region 51v.

Referring to FIG. 5C, the trench 52 may be filled with an insulating layer such as a silicon oxide layer to form a device isolation layer 53. Prior to the formation of the device isolation layer 53, the vertical metal pattern 12v may be removed. According to example embodiments, the active region 51v having uniform width and/or height may be formed.

FIG. 6A is a cross-sectional view of a semiconductor manufacturing apparatus using capacitively-coupled plasma according to an example embodiment.

Referring to FIG. 6A, a semiconductor manufacturing apparatus 1 may be a capacitively-coupled plasma processing apparatus that performs a plasma treatment (e.g., a plasma process) on a substrate 90 mounted on an electrostatic chuck 100 using plasma generated in a capacitively-coupled plasma (CCP) process.

The semiconductor manufacturing apparatus 1 may include the electrostatic chuck 100 supported by a support 1700 and a control unit 200 configured to control operations of the electrostatic chuck 100. The electrostatic chuck 100 may act as a bottom electrode.

The electrostatic chuck 100 may include a temperature sensor 114 detecting a temperature of the electrostatic chuck 100, a base 110 having a channel 112 through which a coolant flows, a heater dielectric layer 140 and an electrostatic dielectric layer 150 bonded onto the base 110, and an annular focus ring 185 surrounding the circumference of the substrate 90, and the heater dielectric layer 140. The heater dielectric layer 140 may include an embedded heater electrode 145, and the electrostatic dielectric layer 150 may include an embedded adsorption electrode 155.

The control unit 200 may include an electrostatic chuck (ESC) power source 210 applying power (e.g., DC voltage) to the adsorption electrode 155, a bias power source 220 applying bias power (e.g., radio frequency (RF)) to the base 110, a temperature adjuster 230 adjusting a flow rate and a temperature of the coolant circulated through the channel 112, a heater power source 240 applying power (e.g., AC voltage) to the heater electrode 145, and a controller 250 controlling the power sources 210, 220 and 240, the temperature adjuster 230 and the temperature sensor 114.

The semiconductor manufacturing apparatus 1 may include a shower head electrode assembly 1101 defining a plasma limitation area 1111 between the shower head electrode assembly 1101 and the electrostatic chuck 100, and a chamber sidewall 1800. A process gas (e.g., an etch gas) supplied from a gas supply 1450 may be introduced to the plasma limitation area 1111 to perform a plasma treatment process on the substrate 90.

The shower head electrode assembly 1101 may have a structure in which a cooling plate 1100, a thermal choke 1200, a heater plate 1300, a shower head 1400, and top electrodes 1510 and 1520 that are stacked. The top electrodes 1510 and 1520 may be thermally controlled by the cooling plate 1100 and the heater plate 1300.

A channel 1110 through which, for example, a coolant flows may be formed inside the cooling plate 1100. The thermal choke 1200 may be provided to control thermal conductivity between the heater plate 1300 and the cooling plate 1100. The thermal choke 1200 may be made of the same or similar material as the heater plate 1300 and/or the cooling plate 1100. The heater plate 1300 may have a circular or concentric circular heater electrode 1310 therein.

The shower head 1400 may have a gas passageway 1410 distributing a processing gas to the plasma limitation area 1111. The top electrodes 1510 and 1520 may be divided into a circular internal electrode 1510 and an annular external electrode 1520 surrounding the circular internal electrode 1510. The gas passageway 1410 may be connected to a gas passageway 1420 penetrating the circular internal electrode 1510. The shower head 1400 may be electrically connected to an RF power source 1460 for plasma generation through an impedance matcher 1462. Thus, a voltage may be applied to the top electrodes 1510 and 1520 from RF power source 1460 via impedance matcher 1462.

The shower head electrode assembly 1101 may include a shroud 1600 connected to the top electrodes 1510 and 1520 and the electrostatic chuck 100 to define the plasma limitation area 1111.

RF power is applied to the top electrodes 1510 and 1520 and/or the electrostatic chuck 100 to generate plasma in the plasma limitation area 1111. Thus, a plasma treatment process may be performed on the substrate 90. The lower layer 11, the metal layer 12, and the mask layer 13 of FIG. 1A may be sequentially stacked on the substrate 90. The breakthrough process and the cyclic process according to example embodiments may be performed in the semiconductor manufacturing apparatus 1.

The etch process and/or the oxidation process may be performed in the semiconductor manufacturing apparatus 1 of FIG. 6A using RF plasma of a capacitively-coupled manner of 13.56 MHz or ultrahigh-frequency plasma of a capacitively-coupled manner of 100 MHz. The electrostatic chuck 100 may be set at a temperature in a range of about 50° C. to about 150° C., e.g., a temperature of about 100° C. A process will be described below in detail.

The breakthrough process described previously in connection with FIG. 1A may be performed using, for example, NF₃ plasma at a pressure lower than the atmospheric pressure (e.g., 100 mTorr). Argon (Ar) may be further contained in the NF₃ plasma. A flow rate of Ar may be about 130 sccm, and a flow rate of NF₃ may be about 30 sccm. In this case, power applied to the top electrodes 1510 and 1520 by the RF power source 1460 (hereinafter referred to as “high power”) may be about 180 W, and power applied to the electrostatic chuck 100 by the bias power source 220 (hereinafter referred to as “low power”) may be about 150 W. The breakthrough process may be performed for a process time of several to tens of seconds (e.g., about 10 seconds). The NF₃ plasma may be provided in a pulsed manner.

The cyclic process described previously in connection with FIGS. 1B to 1G (hereinafter referred to as “first cyclic process”) may be repeated several to tens of times. For example, the first cyclic process may be repeated 20 times to have an etch target of about 2000 Å. In the first cyclic process, a process time of the oxidation process (hereinafter referred to as “first oxidation process”) and a process time of the etch process (hereinafter referred to as “first etch process”) may be equal or similar to each other. When the first oxidation process is performed for a longer process time than the first etch process, etching may be difficult. When the first etch process is performed for a longer process time than the first oxidation process, a bowing phenomenon may occur. Accordingly, a ratio of the process time of the first oxidation process to the process time of the first etch process may be one to one (1:1).

The first oxidation process may be performed using O₂ plasma at a low pressure (e.g., 100 mTorr) lower than the atmospheric pressure. Nitrogen (N₂) may be further contained in the O₂ plasma. A flow rate of oxygen (O₂) may be about 800 sccm, and a flow rate of N₂ may be about 200 sccm. The high power applied to the top electrodes 1510 and 1520 may be about 750 W. Optionally, the low power of about 200 W may be applied to the electrostatic chuck 100 to increase an oxidation rate. The first oxidation process may be performed for the process time of several to tens of seconds (e.g., for the process time ranging from about 5 seconds to about 15 seconds).

The first etch process may be performed using, for example, Cl₂ plasma at a low pressure (e.g., about 10 mTorr) less than the atmospheric pressure. Argon (Ar) may be further contained in the Cl₂ plasma. Each of flow rates of Cl₂ and Ar may be about 100 sccm. The high power applied to the top electrodes 1510 and 1520 may be about 200 W, and the low power applied to the electrostatic chuck 100 may be about 3150 W. The first etch process may be performed for the process time of several to tens of seconds (e.g., for the process time ranging from about 5 seconds to about 15 seconds).

In the first etch process, the Cl₂ plasma may be provided in a pulsed manner. Plasma may be turned on for an on-time of a pulse, and plasma may be turned off for an off-time of the pulse. In example embodiments, a duty ratio of the Cl₂ plasma may be about 10%. In other words, the on-time of the Cl₂ plasma may be 10%, and the off-time of the Cl₂ plasma may be 90%.

Since an etchant needs to go down through the metal layer 12 in the first etch process, the low power (e.g., about 3150 W) greater than the high power (e.g., about 200 W) may be required in the first etch process. Alternatively, since generation and supply of radicals required for oxidation are important factors in the first oxidation process, the high power (e.g., about 750 W) greater than the low power (e.g., about 200 W) may be required in the first oxidation process.

The over-etching process described previously in connection with FIG. 1G may be performed through a cyclic process (hereinafter referred to as “second cyclic process”) in which an oxidation process (hereinafter referred to as “second oxidation process”) and an etch process (hereinafter referred to as “second etch process” are repeatedly performed. In example embodiments, the second cyclic process may be repeated several to tens of times, e.g., seven times to remove the portion 19r of the metal layer 12 shown in FIG. 1G.

The second oxidation process may be performed in a similar condition to the first oxidation process. In example embodiments, the second oxidation process may be performed using, for example, O₂ plasma at a low pressure (e.g., about 200 mTorr) less than the atmospheric pressure for a process time of several to tens of seconds (e.g., for the process time ranging from about 5 seconds to about 15 seconds). Nitrogen (N₂) may be further contained in the O₂ plasma. A flow rate of O₂ may be about 800 sccm, and a flow rate of N₂ may be about 200 sccm. The high power applied to the top electrodes 1510 and 1520 may be about 750 W. According to example embodiments, the low power applied to the electrostatic chuck 100 may be 0 W to prevent the top surface 11t of the lower layer 11 from being oxidized, as shown in FIG. 1G.

The second etch process may be performed in a similar condition to the first etch process. In example embodiments, the second etch process may be performed using, for example, Cl₂ plasma at a low pressure (e.g., about 10 mTorr to about 50 mTorr) less than the atmospheric pressure for a process time of several to tens of seconds (e.g., for the process time ranging from about 5 seconds to about 15 seconds). Argon (Ar) may be further contained in the Cl₂ plasma. Each of flow rates of Cl₂ and Ar may be about 100 sccm. The high power applied to the top electrodes 1510 and 1520 may be about 200 W. According to example embodiments, the low power applied to the electrostatic chuck 100 may be about 4500 W higher than the low power of the first etch process (e.g., about 3150 W) to prevent the top surface 11t of the lower layer 11 from being not opened.

In the second etch process, the Cl₂ plasma may be provided in a pulsed manner. According to example embodiments, a duty ratio of the Cl₂ plasma may be set to about 15% such that an etching time may be made longer to prevent the top surface 11t of the lower layer 11 from being unopened.

The breakthrough process described previously in connection with FIG. 3A may be performed using, for example, Cl₂ plasma at a low pressure (e.g., about 10 mTorr) less than the atmospheric pressure for a process time of several to tens of seconds (e.g., about 25 seconds). Argon (Ar) may be further contained in the Cl₂ plasma. A flow rate of Cl₂ may be about 200 sccm, and a flow rate of Ar may be about 100 sccm. The high power may be about 400 W, and the low power may be about 4000 W. The Cl₂ plasma may be provided in a pulsed manner. In example embodiments, a duty ratio of the Cl₂ plasma may be about 20%.

The etch process described previously in FIG. 3A may be performed using, for example, HBr plasma capable of selectively etching a material (e.g., silicon) of the lower layer 11 at a low pressure (e.g., about 80 mTorr) less than the atmospheric pressure for a process time of several to tens of seconds (e.g., about 25 seconds). At least one of O₂ and NF₃ may be further contained in the HBr plasma. A flow rate of HBr may be about 160 sccm, a flow rate of O₂ may range from about 10 sccm to about 15 sccm (e.g., about 11 sccm), and a flow rate of NF₃ may range from about 30 sccm to about 50 sccm (e.g., about 38 sccm). The high power may be about 400 W, and the low power may be about 3500 W. The HBr plasma may be provided in a pulsed manner. In example embodiments, a duty ratio of the HBr plasma may be about 20%.

FIG. 6B is a cross-sectional view of a semiconductor manufacturing apparatus 2 using inductively-coupled plasma according to an example embodiment.

Referring to FIG. 6B, the semiconductor manufacturing apparatus 2 may be an inductively-coupled plasma processing apparatus that performs a process (e.g., a plasma process) on a substrate 90 mounted on an electrostatic chuck 100 using plasma generated in an inductively-coupled plasma (ICP) process.

As illustrated in FIG. 6B, the semiconductor manufacturing apparatus 2 may include an electrostatic chuck 100 disposed in a central region of a lower region of a cylindrical vacuum chamber 1110 made of a metal, and a control unit 200 controlling the operations of the electrostatic chuck 100. The substrate 90 may be mounted on the electrostatic chuck 100. The electrostatic chuck 100 and the control unit 200 may have the same/similar configuration as described in connection with FIG. 6A, so the descriptions thereto will be omitted.

The electrostatic chuck 100 may be supported by a support 1114 fixed to an inner sidewall of the chamber 1110. A baffle plate 1120 may be provided between the electrostatic chuck 100 and the inner sidewall of the chamber 1110. An exhaust pipe 1124 may be disposed at a lower portion of the chamber 1110, and the exhaust pipe 1124 may be connected to a vacuum pump 1126. A gate valve 1128 may be provided on an outer sidewall of the chamber 1110 to open and close an opening 1127 through which the substrate 90 is put into or taken out of the chamber 1110.

A dielectric window 1152 may be provided under the ceiling of the chamber 1110 so as to be spaced apart from the electrostatic chuck 100. An antenna room 1156 may be provided between the dielectric window 1152 and the ceiling of the chamber 1110. A spiral or concentric circular coil type RF antenna 1154 may be provided in the antenna room 1156. The RF antenna 1154 may be electrically connected to an RF power source 1157 for plasma generation via an impedance matcher 1158. The RF power source 1157 may output RF power suitable for plasma generation. The impedance matcher 1158 may be provided to match an impedance of the RF power source 1157 with an impedance of a load (e.g., the RF antenna 1154). A gas supply source 1166 may supply a processing gas (e.g., an etch gas) to the chamber 1110 via a supply device 1164 such as a nozzle or port hole formed in a sidewall of the chamber 1110.

To perform an etching treatment using the semiconductor manufacturing apparatus 2, the substrate 90 may be put into the chamber 1110 by opening the gate valve 1128 and then be mounted on electrostatic chuck 100. The substrate 90 may be adsorbed to the electrostatic chuck 100 by electrostatic force generated by applying power from the electrostatic chuck (ESC) power source 210 to the electrostatic chuck 100.

An etch gas may be introduced to the chamber 1110 from the gas supply source 1166. The pressure inside the chamber 1110 may be set to a fixed value by the vacuum pump 1126. The power may be applied to the RF antenna 1154 from the RF power source 1157 via the impedance matcher 1158. The power may be applied to the base 110 from the bias power source 220. The electrostatic chuck 100 may serve as a bottom electrode, and the RF antenna 1154 may serve as a top electrode.

The etch gas introduced to the chamber 1110 may be uniformly diffused in a processing room 1172. A magnetic field may be generated around the RF antenna 1154 by a current flowing through the RF antenna 1154, and lines of magnetic force may penetrate the processing room 1172 through the dielectric window 1152. An induced electric field may be generated by time-dependent variation of the magnetic field, and electrons accelerated by the inducted electric field may collide with molecules or atoms of the etch gas to generate plasma. Ions of the plasma may be provided to the substrate 90 to perform the etching treatment. The lower layer 11, the metal layer 12, and the mask layer 13 shown in FIG. 1A may be sequentially stacked on the substrate 90. The cyclic process according to example embodiments may be performed in the semiconductor manufacturing apparatus 2.

The etch process and/or the oxidation process may be performed in the semiconductor manufacturing apparatus 2 of FIG. 6B using RF plasma of an inductively-coupled manner of 13.56 MHz or ultrahigh-frequency plasma of an inductively-coupled manner of 100 MHz. The electrostatic chuck 100 may be set to a temperature in range of about 50° C. to about 150° C., e.g., about 100° C. A detailed process will now be described below.

The breakthrough process described previously in connection with FIG. 1A may be performed using, for example, Cl₂ plasma at a low pressure (e.g., about 15 mTorr) less than the atmospheric pressure. Nitrogen (N₂) may be further contained in the Cl₂ plasma. A flow rate of Cl₂ may be about 200 sccm, and a flow rate of N₂ may be about 20 sccm. In this case, power applied to the RF antenna 1154 by the RF power source 1157 (hereinafter referred to as “high power”) may be about 300 W, and power applied to the electrostatic chuck 100 by the bias power source 220 (hereinafter referred to as “low power”) may range from about 1000 W to about 2500 W. The breakthrough process may be performed for a process time of several to tens of seconds (e.g., about 10 seconds). The NF₃ plasma may be provided in a pulsed manner. In example embodiments, a duty ratio of the NF₃ plasma may be about 20%.

The first cyclic process described previously in connection with FIGS. 1B to 1G may be repeated several to tens of times. In example embodiments, the first cyclic process may be repeated twenty times to have an etch target of about 2000 Å. A ratio of the process time of the first oxidation process to the process time of the first etch process may be one to one (1:1).

The first oxidation process may be performed using O₂ plasma at a low pressure (e.g., about 20 mTorr) less than the atmospheric pressure for a process time of several to tens of seconds (e.g., for the process time ranging from about 5 seconds to about 15 seconds). A flow rate of O₂ may be about 200 sccm. The high power may be about 1000 W. Optionally, the low power may range from about 50 W to about 100 W.

The first etch process may be performed using, for example, Cl₂ plasma at a low pressure (e.g., about 5 mTorr) less than the atmospheric pressure for a process time of several to tens of seconds (e.g., for the process time ranging from about 5 seconds to about 15 seconds). A flow rate of Cl₂ may be about 100 sccm. The high power may be about 300 W, and the low power may range from about 1000 W to about 2500 W. The Cl₂ plasma may be provided in a pulsed manner having a duty ratio of about 10%.

Due to the reason set forth in connection with FIG. 6A, the low power (e.g., about 1000 W to about 2500 W) greater than the high power (e.g., about 300 W) may be required in the first etch process, and the high power (e.g., about 1000 W) greater than the low power (e.g., about 50 W to about 100 W) may be required in the first oxidation process.

The second oxidation process and the second etch process in the over-etching process described previously in connection with FIG. 1G may be performed under similar recipes to the first oxidation process and the first etch process, respectively. For example, the second oxidation process may be performed using O₂ plasma at a low pressure (e.g., about 20 mTorr) for a process time of several to tens of seconds (e.g., about 5 seconds to about 15 seconds). A flow rate of O₂ may be about 200 sccm. The high power may be about 1000 W, and the low power may be 0 W. The second etch process may be performed using Cl₂ plasma of a pulsed manner having a duty ratio of about 10% at a low pressure (e.g., about 5 mTorr) for a process time of several to tens of seconds (e.g., about 5 seconds to about 15 seconds). A flow rate of Cl₂ may be about 100 sccm. The high power may be about 300 W, and the low power may range from about 1000 W to about 25000 W or higher.

The breakthrough process described previously in connection with FIG. 3A may be performed using, for example, CF₄ plasma at a low pressure (e.g., about 10 mTorr) less than the atmospheric pressure for a process time of several to tens of seconds (e.g., about 7 seconds). A flow rate of CF₄ may be about 100 sccm. The high power may be about 100 W, and the low power may range from about 1000 W to about 2500 W. The CF₄ plasma may be provided in a pulsed manner having a duty ratio of about 25%.

The etch process described previously in connection with FIG. 3A may be performed using, for example, Cl₂ plasma at a low pressure (e.g., about 3 mTorr) less than the atmospheric pressure for a process time of several to tens of seconds (e.g., about 7 seconds). Oxygen (O₂) may be further contained in the Cl₂ plasma. A flow rate of Cl₂ may be about 100 sccm, and a flow rate of O₂ may be about 5 sccm. The Cl₂ plasma may be provided in a pulsed manner having a duty ratio of about 20%. Alternatively, the etch process may be performed using HBr plasma of a pulsed manner having a duty ratio of about 25%. At least one of O₂ and NF₃ may be further contained in the HBr plasma.

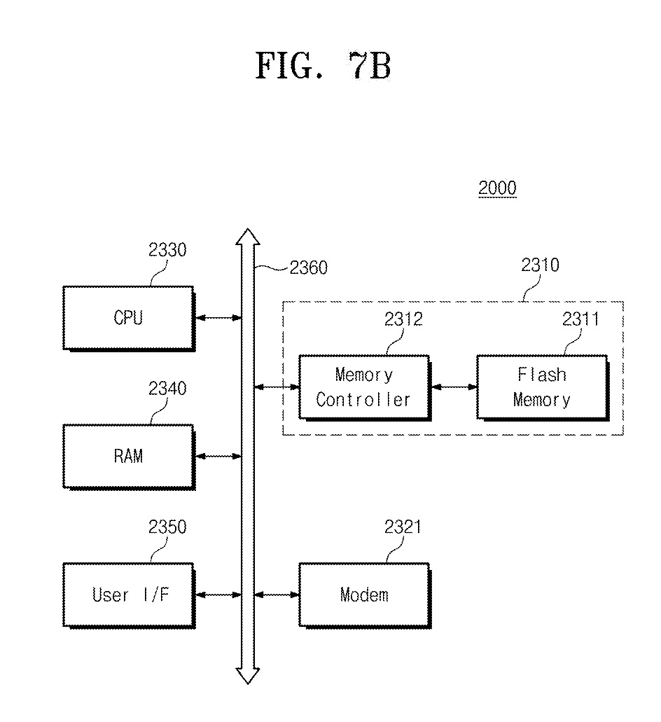

FIG. 7A is a schematic block diagram illustrating a memory card 3000 including a semiconductor device according to example embodiments, and FIG. 7B is a schematic block diagram illustrating an information processing system 2000 including a semiconductor device according to example embodiments.

Referring to FIG. 7A, a memory card 3000 may include a memory 3210 including the above-described semiconductor device. In example embodiments, the memory card 3000 may include a memory controller 3220 to control overall data exchange between a host 3230 and the memory 3210. An SRAM 3221 may be used as a working memory of a central processing unit (CPU) 3222. A host interface (I/F) unit (e.g., circuit) 3223 may include a data exchange protocol of the host 3230 connected to the memory card 3000. An error correction code (ECC) 3224 may detect and correct an error included in data read out of the memory 3210. A memory interface (I/F) unit (e.g., circuit) 3225 may interface with the memory 3210. The CPU 3222 may perform an overall control operation for data exchange of the memory controller 3220.

Referring to FIG. 7B, the information processing system 2000 may include a memory system 2310 including the semiconductor device according to example embodiments. The information processing system 2000 may include mobile devices, mobile and/or stationary computers or computing devices, telephony devices, etc. In example embodiments, the information processing system 2000 may include a modem 2321, a central processing unit (CPU) 2330, a RAM 2340, and a user interface (I/F) unit (e.g., circuit) 2350, each of which are electrically connected the memory system 2310 through a system bus 2360. The memory system 2310 may include a memory 2311 and a memory controller 2312 and may have substantially the same configuration as the memory card 3000 in FIG. 7A. Data processed by the CPU 2330 or external input data may be stored in the memory system 2310.

The information processing system 2300 may be provided to a solid state driver (SSD), a camera image sensor (CIS), and/or other application chipsets. In example embodiments, the memory system 2310 may be configured with an SSD. In such embodiments, the information processing system 2000 may stably and reliably store high-capacity data in the memory system 2310.

As described above, the oxidation process and the etch process are repeatedly performed using oxidation characteristics of tungsten to form the vertical tungsten pattern. Thus, pattern distribution may be improved without formation of an undercut.

The above-disclosed subject matter is to be considered illustrative, and not restrictive, and the appended claims are intended to cover all such modifications, enhancements, and other features, which fall within the true spirit and scope of disclosed embodiments. Thus, to the maximum extent allowed by law, the scope of disclosed embodiments is to be determined by the broadest permissible interpretation of the following claims and their equivalents, and shall not be restricted or limited by the foregoing detailed description. While some example embodiments have been particularly shown and described, it will be understood by one of ordinary skill in the art that variations in form and detail may be made therein without departing from the spirit and scope of the claims.

What is claimed is:

1. A method for forming a pattern, the method comprising:
forming a tungsten layer on a lower layer; and
performing a cyclic process comprising an etch process and an oxidation process on the tungsten layer to form a vertical pattern,
wherein performing the cyclic process comprises:
oxidizing the tungsten layer by the oxidation process using oxygen plasma to form a tungsten oxide layer; and
selectively etching the tungsten oxide layer by the etch process using a chlorine-based gas,
wherein each of the oxidation process and the etch process uses plasma generated by a first power applied to a top electrode and a second power applied to a bottom electrode,
wherein the plasma used in the oxidation process is generated under a condition where the first power is greater than the second power, and
wherein the plasma used in the etch process is generated under a condition where the second power is greater than the first power.

2. The method of claim 1, further comprising:
selectively etching the tungsten layer to form a first hole having a first depth in the tungsten layer,
wherein performing the cyclic process further comprises:
forming a first tungsten oxide layer covering an inner surface of the first hole by the oxidation process; and
selectively removing the first tungsten oxide layer disposed on a floor surface of the first hole by the etch process to expose a portion of the tungsten layer through the floor surface of the first hole.

3. The method of claim 2, wherein the performing the cyclic process further comprises:
further removing the exposed portion of the tungsten layer by the etch process to form a second hole having a second depth greater than the first depth; and
forming a second tungsten oxide layer covering an inner surface of the second hole by the oxidation process.

4. The method of claim 2, wherein the selectively removing the first tungsten oxide layer comprises:
allowing a portion of the first tungsten oxide layer to remain on an inner sidewall of the first hole.

5. The method of claim 2, further comprising:
forming a mask layer on the tungsten layer,
wherein the selectively removing the tungsten layer to form a first hole comprises:
etching the tungsten layer to form the first hole by an etch process using the mask layer as an etch mask.

6. The method of claim 5, wherein the etching the tungsten layer to form the first hole further comprises:
forming a polymer layer on the mask layer, the polymer layer including an etching by-product generated during the formation of the first hole, and
wherein the polymer layer is removed by the oxidation process.

7. The method of claim 1, wherein the oxygen plasma further includes hydrogen or a hydrocarbon-based gas including hydrogen.

8. The method of claim 1, wherein the etch process uses a mixed gas in which at least one of boron, a boron-containing gas or an inert gas is mixed with the chlorine-based gas.

9. The method of claim 1, further comprising:
patterning the lower layer by means of an etch process using the vertical pattern as an etch mask.

10. The method of claim 9, wherein the lower layer includes at least one of a silicon layer, a silicon oxide layer, or a silicon oxynitride layer.

11. A method for forming a pattern, the method comprising:
forming a tungsten-containing layer on a lower layer;
forming a mask layer on the tungsten-containing layer;
patterning the tungsten-containing layer by means of an etch process using the mask layer as an etch mask to form a hole in the tungsten-containing layer;
oxidizing the tungsten-containing layer by means of an oxidation process using oxygen plasma such that a tungsten oxide layer is formed to cover an inner surface of the hole;
etching the tungsten oxide layer by means of an etch process using a chlorine-based gas to selectively remove the tungsten oxide layer on a floor surface of the inner surface of the hole and to allow the tungsten oxide layer to remain on an inner sidewall of the inner surface of the hole; and
removing the tungsten-containing layer exposed through the floor surface of the hole by means of the etch process using the chlorine-based gas,
wherein the oxidation process using the oxygen plasma and the etch process using the chlorine-based gas are performed in a chamber to which opposite top and bottom electrodes are provided,
wherein the oxidation process uses plasma generated under a condition where a first power applied to the top electrode is greater than a second power applied to the bottom electrode, and
wherein the etch process uses plasma generated under a condition where the second power applied to the bottom electrode is greater than the first power applied to the top electrode.

12. The method of claim 11, further comprising:
after removing the tungsten-containing layer exposed through the floor surface of the hole by means of the etch process using the chlorine-based gas, performing the oxidation process using the oxygen plasma and the etch process using the chlorine-based gas one or more times to increase a depth of the hole, thereby exposing the lower layer.

13. The method of claim 11, wherein the tungsten-containing layer includes a tungsten (W) layer or a tungsten nitride (WN) layer, and
wherein the tungsten oxide layer includes a WO layer.

14. The method of claim 11, wherein the chlorine-based gas contains Cl₂, CCl₄, BCl₃ or a combination thereof.

15. The method of claim 14, wherein the etch process using the chlorine-based gas uses a mixed gas in which boron (B) or BCl₃ is mixed with the Cl₂, CCl₄, BCl₃ or the combination thereof.

16. The method of claim 11, wherein the oxygen plasma includes oxygen (O₂) and a gas adjusting an oxidation rate of the tungsten-containing layer, and
wherein the gas adjusting the oxidation rate of the tungsten-containing gas includes H₂, CH₄, CHF₃, CH₃F, C₂H₆, C₂H₄, or a combination thereof.

17. A method for forming a pattern, the method comprising:
loading a substrate having a metal layer thereon on a bottom electrode in a chamber, the chamber including a top electrode and the bottom electrode;
performing a cyclic process to pattern the metal layer; and
repeatedly performing the cyclic process to form a vertical pattern on the substrate,
wherein performing the cyclic process comprises:
oxidizing the metal layer by means of an oxidation process using oxygen plasma generated under a condition where a first power applied to the top electrode is greater than a second power applied to the bottom electrode, thereby forming a passivation covering a surface of the metal layer; and
selectively removing the passivation layer by means of an etch process using chlorine-based gas plasma generated under a condition where the second power applied to the bottom electrode is greater than the first power applied to the top electrode, thereby exposing a portion of the surface of the metal layer, and
wherein the repeatedly performing the cyclic process comprises successively removing the exposed portion of the surface of the metal layer to form the vertical pattern.

18. The method as of claim 17, wherein the metal layer includes tungsten,
wherein the passivation layer includes a tungsten oxide layer, and
wherein a ratio of a process time of the oxidation process to a process time of the etch process is one to one (1:1).

19. The method of claim 17, wherein performing the cyclic process to pattern the metal layer comprises forming a hole partially penetrating the metal layer to extend toward the substrate, and
wherein the cyclic process is repeatedly performed to increase a depth of the hole.

20. The method of claim 19, wherein the passivation layer covers an inner sidewall of the hole, and
wherein the etch process removes a portion of the passivation layer covering a floor surface of the hole.
